(19) United States
(12) Patent Application Publication
(10) Pub. No.: US 2004/0118346 A1
(43) Pub. Date: Jun. 24, 2004

(54) Deposited-film formation apparatus, and deposited-film formation process

(76) Inventors: Takahiro Yajima, Kyoto (JP); Masahiro Kanai, Tokyo (JP); Takeshi Shishido, Kyoto (JP)

Correspondence Address: FITZPATRICK CELLA HARPER & SCINTO, 30 ROCKEFELLER PLAZA, NEW YORK, NY, 10112, US

(21) Appl. No.: 10/733,452

(22) Filed: Dec. 12, 2003

Related U.S. Application Data
(62) Division of application No. 09/769,328, filed on Jan. 26, 2001.

(30) Foreign Application Priority Data
Jan. 31, 2000 (JP) 2000-021663
Jan. 23, 2001 (JP) 2001-014446

(51) Int. Cl. C23C 16/00

(52) U.S. Cl. 118/723 E

(57) ABSTRACT

The surface shape of a power-applying electrode is altered in agreement with the curving of a substrate so that the electrode-substrate distance can be kept at a constant value. This enables formation of thin films having uniform film thickness in the substrate width direction even when the electrode-substrate distance is shortened in order to make film formation rate higher in deposited-film formation apparatus of a roll-to-roll system.

### BACKGROUND OF THE INVENTION

1. Field of the Invention

This invention relates to an apparatus, and a process, for forming a thin film on a substrate by generating plasma between a power-applying electrode and the substrate in a vacuum chamber, the substrate being servable as an electrode disposed opposingly to the power-applying electrode.

2. Related Background Art

As typical electronic devices that make use of the photovoltaic effect, solar cells are known, for example. Solar cells convert solar energy or other light energy to electric energy, and have attracted notice as a clean energy source as a part of future policy for energy.

Amorphous semiconductors as exemplified by amorphous silicon can be formed in thin film and can be made to have a large area, and have a high degree of freedom of composition to enable control of electrical and optical characteristics in a wide range. Accordingly, they are recently utilized as materials for various devices. In particular, amorphous silicon has a greater absorption factor than crystalline silicon with respect to light at a peak and in the vicinity thereof in the energy distribution of sunlight. It also has characteristic features that a low film formation temperature can be used and films can be formed directly on the substrate by glow discharging from materials gases. Accordingly, it has attracted notice as a material for solar cells.

In such solar cells regarded important as a part of future new policy for energy, it is a pressing important subject of research and development to make them lower-price and higher-performance. As solar cell materials that can materialize the lower price, the amorphous silicon formable in thin film has attracted notice. Until know, in view of performance, those having a reasonably high conversion efficiency have come to be obtainable. In view of the lower price, they are still unsatisfactory. A reason therefor is a low film formation rate. In the case of p-i-n type amorphous-silicon solar cells produced by glow discharge decomposition, i-type layers are conventionally formed at a low rate of 0.1 to 2 angstrom/sec, and hence it has taken a time of from 30 minutes to about 2 hours until an i-type film of 4,000 angstrom thick is formed up. As a method of forming amorphous silicon films at a high rate, it is attempted to use 100% SiH₄ gas or 100% Si₂H₆ gas. Also, it is possible to form films at a higher rate by making the distance short between the power-applying electrode and the substrate servable as an electrode, as disclosed in Japanese Patent Publication No. 5-56850.

As a method for improving mass productivity of amorphous silicon solar cells, there is a roll-to-roll system as disclosed in Japanese Patent Application Laid-open No. 6-23243. This system is a system basically constituted of a plurality of discharge chambers in which amorphous silicon films are formed, and a beltlike substrate which passes through these discharge chambers and through gas gates provided to connect the discharge chambers and at the same time separate atmospheres in the discharge chambers from one another, where functional thin films of amorphous silicon or the like are continuously deposited on the beltlike substrate, and the substrate with deposited films is successively wound up, promising a superior mass productivity.

In the roll-to-roll system, however, a thin beltlike substrate is only held under tension without being fixed to a substrate holder or the like, and hence it may deform because of curving or warpage. Also, in order to form amorphous silicon films having a good quality, it is necessary for the substrate to be heated to a high temperature of 100° C. or above, and the substrate may further deform because of heat when a flexible substrate is used.

Where the electrode-substrate distance is great, the deformation of the beltlike substrate may be relatively small in the discharge space, and hence it may less affect the film formation rate for the thin films to be obtained. However, when the electrode-substrate distance is shortened in order to form amorphous silicon films at a higher rate, even a slight deformation of the substrate may cause a difference in the electrode-substrate distance to greatly affect the film formation rate distribution for the thin films to be obtained.

Where a beltlike substrate having been curved by tension is used, the discharge space comes not to have any constant cross-sectional area in the substrate transport direction or in the direction (substrate width direction) perpendicular to the gas flow direction, so that there come to be part where gas flows in a large quantity and part where it flows in a small quantity, to cause uneven film formation rate in the substrate width direction.

Thus, when the electrode-substrate distance is shortened, it has been difficult to obtain thin films having a film thickness that is uniform in the substrate width direction, because of curving of the beltlike substrate.

### SUMMARY OF THE INVENTION

Taking account of the problems the prior art has had, an object of the present invention is to provide, in the deposited-film formation apparatus of a roll-to-roll system, a deposited-film formation apparatus and a deposited-film formation process which enable formation of thin films having a film thickness that is uniform in the substrate width direction even when the electrode-substrate distance is shortened in order to form the films at a higher rate.

To achieve the above object, the present invention provides as an embodiment thereof a deposited-film formation apparatus for forming a deposited film on a substrate by;

generating plasma in a discharge space defined between a power-applying electrode and the substrate in a vacuum chamber, the substrate being servable as an electrode disposed opposingly to the power-applying electrode; and

decomposing a material gas fed into the vacuum chamber, wherein;

the substrate has a flexibility, and the power-applying electrode is provided with an undulation on its surface on the side of discharge space in such a way that the distance between the substrate and the power-applying electrode comes to be a desired value in agreement with the curving of the substrate.

This undulation may preferably be formed in agreement with the curving of the substrate in the course of its transportation.

The present invention also provides, as another embodiment thereof, a deposited-film formation apparatus for forming a deposited film on a substrate by;

generating plasma in a discharge space defined between a power-applying electrode and the substrate in a vacuum chamber, the substrate being servable as an electrode disposed opposingly to the power-applying electrode; and

decomposing a material gas fed into the vacuum chamber, wherein;

the power-applying electrode has a structure comprising a plurality of sheets or a plurality of columnar members which are bundled upright with respect to the substrate.

In this embodiment, the substrate may preferably have a flexibility, and the power-applying electrode may preferably be an electrode which is pressed against the surface of the substrate in such a way that individual sheets or individual columnar members constituting the power-applying electrode come into contact with that surface at their upper ends so that a curved shape of the substrate is transferred to the surface of the power-applying electrode.

A means for pressing the power-applying electrode against the surface of the substrate in such a way that individual sheets or individual columnar members constituting the power-applying electrode come into contact with that surface at their upper ends may further be provided at the power-applying electrode on its side opposite to the substrate side.

The surface that connects substrate-side ends of the plurality of sheets or plurality of columnar members may also preferably be so formed as to be in agreement with the curving of the substrate in the course of its transportation.

In the present invention, when referred to as “so formed as to be in agreement with the curving”, it is so formed that the distance between the power-applying electrode and the substrate is in a variation within 20%.

The present invention also provides, as an embodiment of the deposited-film formation process, a process comprising the steps of:

generating plasma in a discharge space defined between a power-applying electrode and the substrate in a vacuum chamber, the substrate being servable as an electrode disposed opposingly to the power-applying electrode; and

decomposing a material gas fed into the vacuum chamber, to form a deposited film on the substrate,

wherein;

the inside of the vacuum chamber is brought into conditions for forming the deposited film, and the deposited film is formed by generating the plasma after the power-applying electrode, constituted of a plurality of sheets or a plurality of columnar members which are bundled upright with respect to the substrate, is so pressed against the substrate as to come into contact with its surface to transfer a curved shape of the substrate to the surface of the power-applying electrode and then the power-applying electrode is separated from the surface of the substrate.

In another embodiment of the deposited-film formation process, the process may comprise the step of:

generating plasma in a discharge space defined between a power-applying electrode and the substrate in a vacuum chamber, the substrate being servable as an electrode disposed opposingly to the power-applying electrode; and

decomposing a material gas fed into the vacuum chamber, to form a deposited film on the substrate while the substrate is transported,

wherein;

the process further comprises the steps of:

providing the power-applying electrode with an undulation on its surface in agreement with the curving of the substrate in the course of its transportation; and

disposing the power-applying electrode in the vacuum chamber.

In this embodiment, it is preferred that undulation on a surface of the substrate in the course of its transportation is expected by simulation, trial experiments or the like and undulation is provided on a surface of the electrode based on the results of the expectation.

According to the present invention constituted as described above, in the deposited-film formation apparatus and deposited-film formation process in which plasma is generated in a discharge space defined between a power-applying electrode and a substrate opposing thereto, in particular, in the deposited-film formation apparatus of the type the substrate is transported using the roll-to-roll system, the surface shape of the power-applying electrode on the side of the discharge space is brought into agreement with the curving of the substrate which is caused, e.g., by applying tension especially when the substrate is transported in the roll-to-roll system. This enables the electrode-substrate distance to be kept substantially constant. Hence, even when the distance between the power-applying electrode and the substrate opposing thereto is shortened in order to form films at a higher rate, any unevenness of film formation rate in the substrate width direction can be made small and any disturbance of gas flow in the substrate width direction can be made small, so that thin films having a film thickness which is uniform in the substrate width direction can be obtained.

### BRIEF DESCRIPTION OF THE DRAWINGS

FIG. 1 is a schematic cross-sectional illustration of a deposited-film formation apparatus according to an embodiment of the present invention.

FIG. 2 is a diagrammatic cross-sectional view of a power-applying electrode and a substrate which are used as Example 1 of the present invention.

FIGS. 3A, 3B and 3C are diagrammatic cross-sectional views of a power-applying electrode and a substrate which are used as Example 2 of the present invention.

FIGS. 4A, 4B and 4C are diagrammatic cross-sectional views of a power-applying electrode and a substrate which are used as Example 3 of the present invention.

FIG. 5 is a diagrammatic view of the film thickness of a thin film obtained in Comparative Example for the present invention, represented by isopachic lines.

FIG. 6 is a diagrammatic view of the film thickness of a thin film obtained in Example 1 of the present invention, represented by isopachic lines.

FIG. 7 is a graph showing the correlation of film formation rate non-uniformity r in the substrate width direction (the ratio of a minimum value rₘᵢₙ to a difference between a maximum value rₘₐₓ and the minimum value rₘᵢₙ, i.e., (rₘₐₓ−rₘᵢₙ)/rₘᵢₙ) with electrode-substrate distance variation t (the ratio of a minimum value tₘᵢₙ to a difference between a maximum value tₘₐₓ and the minimum value tₘᵢₙ, i.e., (tₘₐₓ−tₘᵢₙ)/tₘᵢₙ).

FIG. 8 is a diagrammatic cross-sectional view of a power-applying electrode and a substrate which are used in conventional commonly available deposited-film formation apparatus.

### DESCRIPTION OF THE PREFERRED EMBODIMENTS

Embodiments of the present invention will be described below with reference to the accompanying drawings.

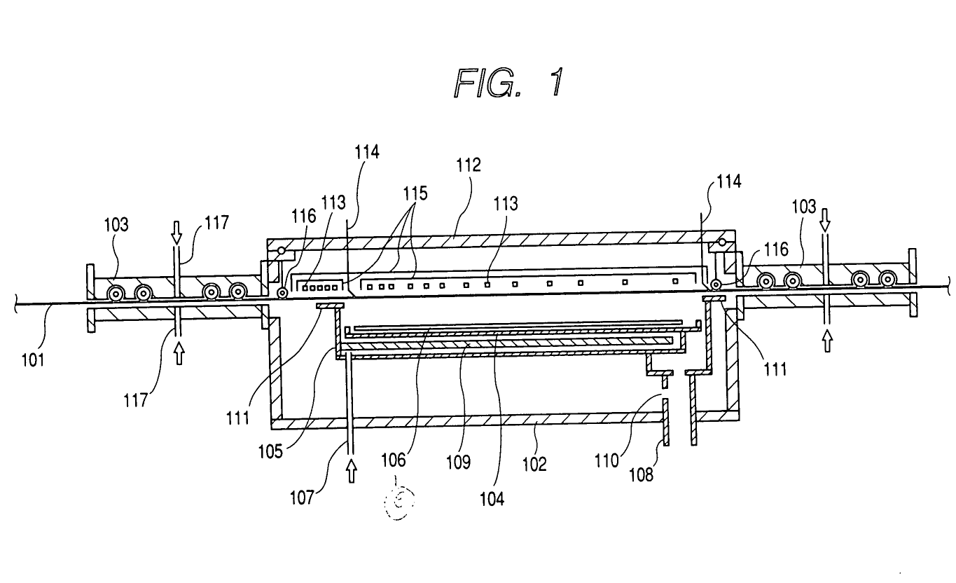

The deposited-film formation apparatus of the present invention may include an embodiment of a parallel-plate capacitive coupling type deposited-film formation apparatus as shown in FIG. 1. FIG. 1 is a schematic cross-sectional illustration of such a deposited-film formation apparatus according to an embodiment of the present invention. The apparatus shown in FIG. 1 is basically constituted of a rectangular vacuum chamber 102 connected with other vacuum chambers adjacently provided through gas gates 103, a discharge chamber 105 provided inside the vacuum chamber 102, and a beltlike substrate 101 led into the discharge chamber 105, passing through the gas gates 103. Into the gas gates 103, gas such as H₂ or He is fed through a gas feed pipe 117 so that the atmospheric gas and pressure inside vacuum chambers adjacent to each other can be separated.

The discharge chamber 105 provided inside the vacuum chamber 102 has a hollow rectangular shape, one side of which discharge chamber forms an opening, and the opening is provided in proximity to the beltlike substrate 101. The beltlike substrate 101, having been led into the discharge chamber 105, is heated with a lamp heater 113 and is temperature-controlled by means of a thermocouple 114. Inside the discharge chamber 105, a parallel-plate type power-applying electrode 106 is provided, to which an electric power can be supplied from a high-frequency power source (not shown) to cause plasma in the discharge chamber 105.

Material gas is fed into the discharge chamber 105 through a material gas feed pipe 107 passing through the wall of the vacuum chamber, and then heated with a block heater 109. The discharge chamber 105 is provided with an exhaust tube 108 through which the material gas is exhausted. The material gas flows in parallel to the transport direction of the beltlike substrate 101 and flows over the power-applying electrode 106 of the discharge chamber 105. Thereafter, it is exhausted out of the discharge chamber and further out of the vacuum chamber to the outside. A part of the gas gate gas and material gas in the vacuum chamber is exhausted through a discharge chamber external exhaust vent 110 provided at some part of the exhaust tube 108.

In the vicinity of a material gas blow outlet, undecomposed gas is present in a large quantity in the plasma, and hence films may be formed in non-uniform thickness and in a low quality. In the vicinity of the exhaust vent, too, films may often be formed in a low quality because of disorder of the plasma. Especially in the apparatus of a roll-to-roll system, film deposition at these portions in the vicinity of gas blow outlet and in the vicinity of the exhaust vent may cause formation of, e.g., an n/i interface and a p/i interface which affect characteristics of solar cells greatly, and hence, in order to cover the regions of such film formation, opening adjuster plates 111 for intercepting plasma are provided at the gas blow-out part and exhaust vent part as shown in FIG. 1.

Incidentally, in the present specification, an electrode which applies electric power or an electrode opposing the substrate is called the power-applying electrode. To this power-applying electrode, electric power including direct-current electric power or electric power of a low frequency of from 5 kHz to 500 kHz, a high frequency of from 500 kHz to 30 MHz or a VHF of from 30 MHz to 500 MHz may be applied to generate direct-current plasma, low-frequency plasma, high-frequency plasma or VHF plasma, respectively, where gases are decomposed to deposit semiconductor thin films on the substrate.

The substrate is a substrate having a flexibility and may be a substrate attached to a substrate holder or a continuous-length beltlike substrate wound in a coil. The beltlike substrate may be a substrate obtained by forming a conductive thin film on a flexible insulating material such as a polymeric film, or a flexible conductive substrate such as stainless steel sheet. The continuous-length beltlike substrate is required to have a small thickness so that the substrate wound in a coil does not have a heavy weight. This, however, makes the substrate tend to deform because of tension or heat, and holds great expectation for the effect of the present invention.

The distance between the power-applying electrode and the substrate is set not larger than 50 mm in order to enhance film formation rate. In order to generate highly stable plasma, it may preferably be set not smaller than 5 mm. It may more preferably be within the range of from 10 mm to 30 mm.

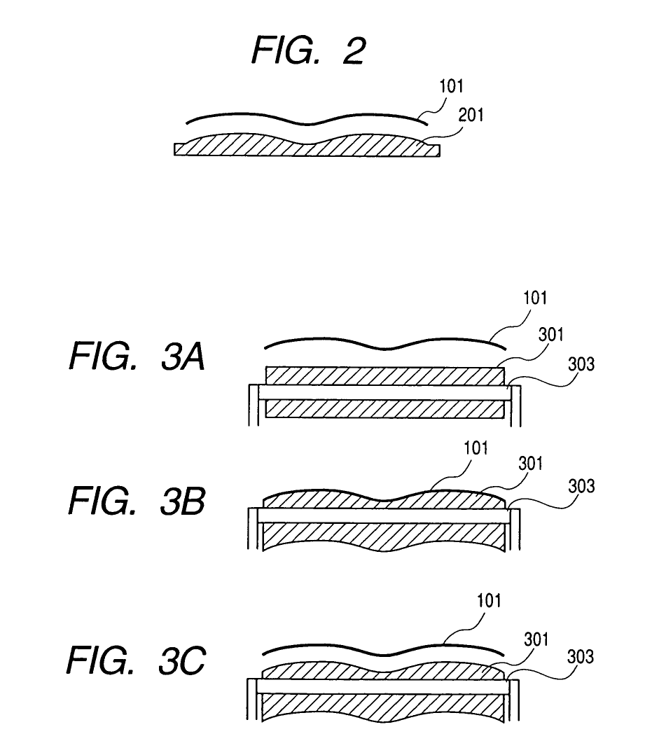

Diagrammatic representations of embodiments of the power-applying electrode and substrate according to the present invention are shown in FIG. 2 to FIGS. 4A to 4C. Incidentally, an example in conventional commonly available apparatus is shown in FIG. 8.

The power-applying electrode may be any of a power-applying electrode provided on its side facing the discharge space, with an undulation in agreement with the shape of the substrate as shown in FIG. 2, and a power-applying electrode formed of a plurality of sheets which are bundled upright and can lightly be pressed against the substrate surface to become surface-shaped after the undulation of the substrate as shown in FIGS. 3A to 3C. Also, in place of the plurality of sheets, the power-applying electrode may be constituted of a plurality of columnar members bundled upright.

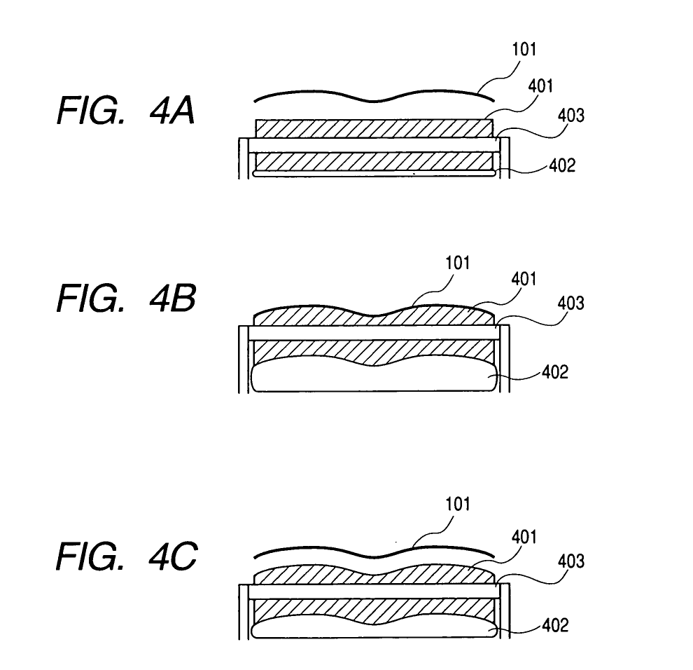

An up-and-down means 402 for lifting up the electrode may also additionally be provided beneath the power-applying electrode as shown in FIGS. 4B and 4C. It may preferably be a gas pressure bag into which a gas can be fed through a plurality of gas feed pipes to inflate the bag. As its material, it may preferably have both insulating properties and heat resistance. After the electrode has been lifted up and the deflection of the substrate has been transferred to the electrode surface, the gas may be let out of the gas pressure bag to descend the electrode in order to set the electrode and the substrate at the desired distance. Also, the deposited-film formation apparatus may be provided with a sight window through which the electrode-substrate distance is checked in a vacuum state. Alternatively, the electrostatic capacity of a flat substrate and that of an electrode standing surface-flat may previously be measured in a vacuum state or under conditions for forming deposited films so that the electrode-substrate distance can be checked by making reference to the measured values.

The present invention will be described below in greater detail by giving Examples on the shape of the power-applying electrode and substrate according to the present invention. In the following, the same parts as component parts of the apparatus shown in FIG. 1 as an example in which the present invention is applied are described using the same reference numerals as those in FIG. 1.

### EXAMPLE 1

FIG. 2 is a diagrammatic cross-sectional illustration of a power-applying electrode and a substrate which are used as Example 1 of the present invention. This drawing is a cross section made by cutting them in the direction perpendicular to the substrate transport direction or gas flow direction. In the present Example, the thickness of a power-applying electrode 201 is made to partly differ in agreement with the previously measured deflection (curving) of a substrate 101 so that the electrode-substrate distance can be kept at a desired value (a constant value). In other words, the discharge space is kept to have a constant cross-sectional area in the substrate width direction. Application of tension (stretch) for the transport of the substrate in the roll-to-roll system makes the substrate to deflect in the substrate width direction as shown in FIG. 2. Transporting this substrate causes a change also in the extent of deflection in fixed-point measurement. Measurement of the substrate deflection with a laser displacement sensor has proved that the change (variation) in the extent of deflection of the substrate is within the range of plus-minus 2 mm without regard to transport speed. Incidentally, the extent of deflection of the substrate can be measured with, besides the laser displacement sensor, an ultrasonic displacement sensor, an eddy current displacement sensor or a contact type displacement sensor.

The power-applying electrode 201 shown in FIG. 2 was used at the part of the power-applying electrode 106 of the apparatus shown in FIG. 1, and a mixed gas of SiH₄ gas and H₂ gas was flowed in the discharge chamber 105. Then, a high-frequency power with a frequency of 13.56 MHz was applied to the power-applying electrode to cause plasma, where an amorphous silicon thin film was formed for 5 minutes, keeping the beltlike substrate 101 to stand still.

In order to achieve a high film formation rate, the distance between the power-applying electrode 201 and the substrate 101 was set at 15 mm.

As Comparative Example, using a power-applying electrode 801 having a flat surface as shown in FIG. 8, an amorphous silicon thin film was formed on the beltlike substrate 101 in the same manner as in Example 1.

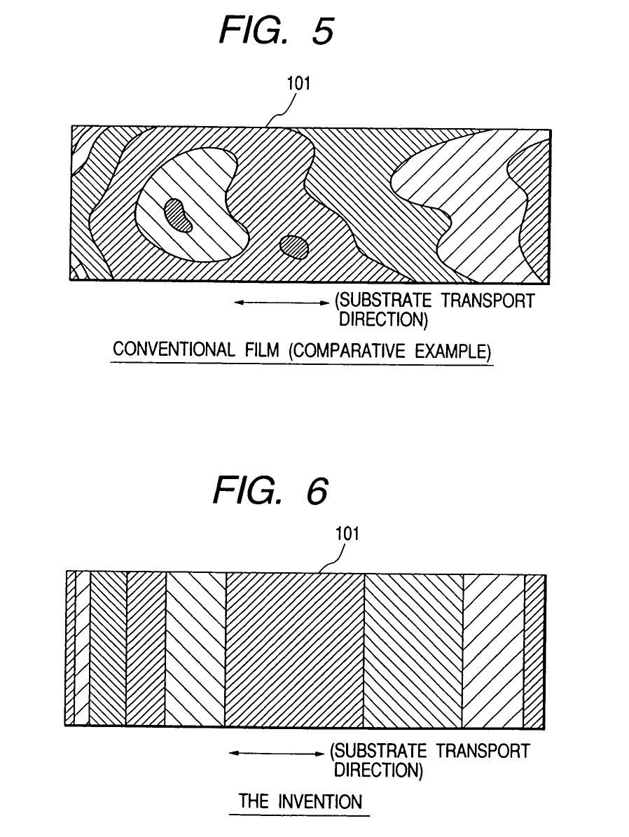

FIG. 5 is a diagrammatic view of the film thickness of a thin film obtained in Comparative Example, represented by isopachic lines. In Comparative Example, the film was formed in an uneven thickness not only in the gas flow direction but also in the substrate width direction perpendicular to the gas flow. This is due to the fact that the substrate 101 deflects to cause a variation in distance between the power-applying electrode 801 and the substrate 101 as shown in FIG. 8. This variation may occur in a remarkable difference especially when the electrode-substrate distance is shortened as in the present Example, so that the material gas also may partly flow with ease and partly flow with difficulty to cause a local non-uniformity in the material gas flow rate. Moreover, the variation of the electrode-substrate distance results in a variation in the film formation rate, too. As the result of these, the distribution of film formation rate has become great in the substrate width direction, as so presumed.

FIG. 6 diagrammatically illustrates the film thickness of a thin film obtained in the present Example 1, represented by isopachic lines. Although there is uneven film thickness in the direction of gas flow, the uniformity in film thickness in the substrate width direction has substantially perfectly been improved.

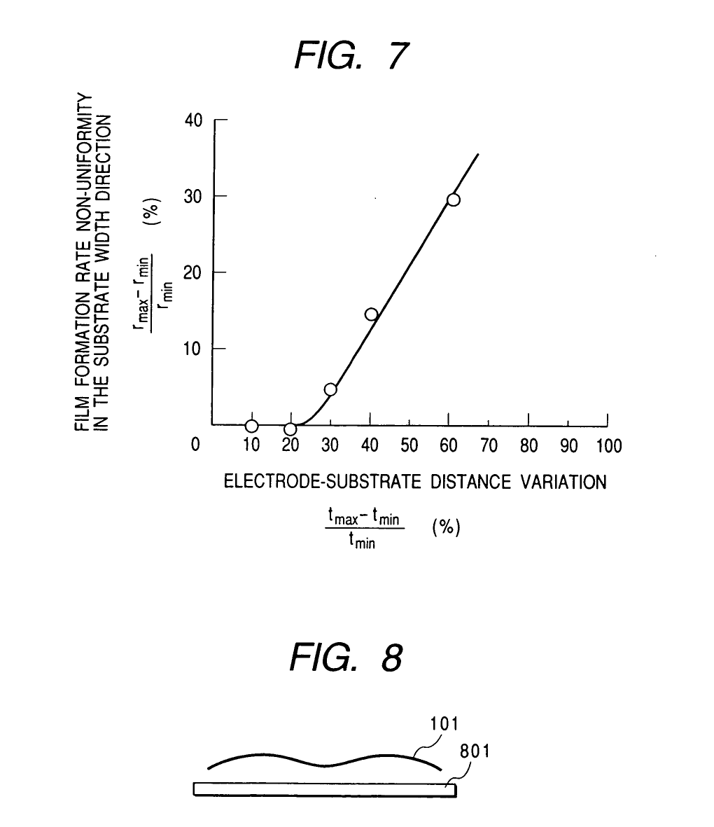

Now, the correlation between the variation in electrode-substrate distance that is due to the deflection of the substrate as shown in FIG. 2 and the non-uniformity in film formation rate in the substrate width direction was examined. Since it is very difficult for the substrate and electrode to come in prefect agreement in shape, the thickness of the electrode was partially changed to change the ratio of maximum value to minimum value of the substrate width direction, where a thin film was deposited. To make definition of the non-uniformity in film formation rate of the film formed, a difference between maximum value and minimum value of the film formation rate at points positioned in the direction (substrate width direction) perpendicular to the gas flow direction on an arbitrary point (the middle was picked up in the present Example) of the thin film was multiplied by the minimum value. FIG. 7 shows the correlation of film formation rate non-uniformity r in the substrate width direction (the ratio of a minimum value rₘᵢₙ to a difference between a maximum value rₘₐₓ and the minimum value rₘᵢₙ, i.e., (rₘₐₓ−rₘᵢₙ)/rₘᵢₙ) with electrode-substrate distance variation t (the ratio of a minimum value tₘᵢₙ to a difference between a maximum value tₘₐₓ and the minimum value tₘᵢₙ, i.e., (tₘₐₓ−tₘᵢₙ)/tₘᵢₙ) As shown in FIG. 7, it was found that the film formation rate non-uniformity in the substrate width direction increases abruptly when the electrode-substrate distance variation is greater than 20%.

### Example 2

FIGS. 3A to 3C diagrammatically cross-sectionally illustrate a power-applying electrode and a substrate which are used as Example 2 of the present invention. Like FIG. 2, these drawings are cross sections made by cutting the electrode and substrate in the direction perpendicular to the substrate transport direction or gas flow direction. In the present Example, an electrode having a structure comprising a plurality of thin sheets put together upright with respect to the substrate and bundled with an electrode fixing band 303 is used as a power-applying electrode 301. Slender holes are made in the thin sheets and a through-rod is passed through the holes and fixed on both ends of the electrode fixing band so that the thin sheets put together can be prevented from becoming loose. Also, sheet members constituting the power-applying electrode 301 may each preferably be disposed along the substrate transport direction or gas flow direction.

With such construction, before film formation processing is started, the power-applying electrode 301 is lifted up and pressed against the substrate 302 surface to become surface-shaped after the shape of deflection of the substrate 101. The sheets constituting the electrode 301 each so slip or slide vertically that their upper ends come in contact with the surface of the substrate 101, so that the electrode becomes surface-shaped after the surface shape of the substrate (see FIG. 3B). Thereafter, the sheet members of the electrode 301 standing surface-shaped after the surface shape of the substrate are each fixed in that state, and then the electrode 301 is descended to a height providing the desired electrode-substrate distance (see FIG. 3C). In this way, the shape of deflection of the substrate is transferred to the power-applying electrode as secondary information.

The power-applying electrode 301 shown in FIGS. 3A to 3C was used at the part of the power-applying electrode 106 shown in FIG. 1, and an amorphous silicon thin film was deposited on the beltlike substrate 101 in the same manner as in Example 1. Incidentally, the distance between the power-applying electrode 301 and the beltlike substrate 101 was set at 15 mm.

In the present Example, too, like Example 1 the thin film was formed in a uniform film thickness. The film was in substantially the same film thickness distribution as that shown in FIG. 6, thus it was formable at a constant film formation rate in the substrate width direction. Employment of the present Example enables the electrode to be surface-shaped after the shape of deflection of the substrate with ease, whatever substrates are used. Thus, uniform formation of thin films can be achieved relatively with ease, without preparing any power-applying electrode having a special shape as in Example 1.

### EXAMPLE 3

FIGS. 4A to 4C diagrammatically cross-sectionally illustrate a power-applying electrode and a substrate which are used as Example 3 of the present invention. Like FIG. 2, these drawings are cross sections made by cutting the electrode and substrate in the direction perpendicular to the substrate transport direction or gas flow direction. In the present Example, an electrode having a structure comprising a plurality of columnar members put together upright with respect to the substrate and bundled with an electrode fixing band 403 is used as a power-applying electrode 401. A gas pressure bag 402 is further provided at the lower part of the power-applying electrode 401 so that the height of the electrode 401 can be regulated even from the outside of the vacuum chamber. Since the power-applying electrode 401 of the present Example is constituted of a plurality of columnar members bundled upright, it can be surface-shaped after the shape of any deflection of the substrate.

With such construction, gas such as compressed air or N₂ gas may be fed into the gas pressure bag 402 from the outside of the vacuum chamber to lift up the electrode 401, so that upper ends of the columnar members constituting the electrode 401 are each pressed against the surface of the substrate 101 to come into contact with that surface. Thus, the electrode 401 becomes surface-shaped after the shape of deflection of the substrate 101 (see FIG. 4B). Thereafter, the columnar members of the electrode 401 standing surface-shaped after the surface shape of the substrate are each fixed in that state, and then the gas in the gas pressure bag 402 is let out to descend the electrode 401 to a height providing the desired electrode-substrate distance (see FIG. 4C). Here, the gas pressure bag was made of an insulating heat-resistant material, and the electrode-substrate distance was regulated watching it through a sight window provided in the sidewall of the vacuum chamber.

The power-applying electrode 401 shown in FIGS. 4A to 4C was used at the part of the power-applying electrode 106 shown in FIG. 1, and an amorphous silicon thin film was deposited on the beltlike substrate 101 in the same manner as in Example 1. Incidentally, the distance between the power-applying electrode 401 and the beltlike substrate 101 was set at 10 mm.

In the present Example, the electrode-substrate distance was shorter than that in Examples 1 and 2 and the film formation rate should have tended to become non-uniform in the substrate width direction. Nonetheless, like Examples 1 and 2 the thin film was formed in a uniform film thickness, and was formable at a constant film formation rate in the substrate width direction. Thus, although the deflection of the substrate may vary depending on the strength of tension during transport, substrate materials and heating temperature, the employment of the present Example enables the electrode to be accurately surface-shaped after the shape of deflection of the substrate in a state close to conditions for film formation, whatever substrates are-used. Thus, uniform formation of thin films can be achieved relatively with ease, without preparing any power-applying electrode having a special shape as in Example 1.

The gas pressure bag 402 also made the electrode 401 have no gap on its back, so that any abnormal discharging or polysilane powder (dust) was kept from occurring on the electrode back, while the electrode-substrate distance was changed.

As described above, in the present invention, in the deposited-film formation apparatus for forming a deposited film on a substrate by generating plasma in a discharge space defined between a power-applying electrode and the substrate in a vacuum chamber, the substrate being servable as an electrode disposed opposingly to the power-applying electrode, and decomposing a material gas fed into the vacuum chamber, the surface shape of the power-applying electrode is altered in agreement with the curving of the substrate to make the electrode-substrate distance constant. Thus, thin films can be formed at a film formation rate having been made uniform in distribution in the substrate width direction. This makes it possible to provide thin-film devices such as solar cells at a lower cost and in a larger area, bringing about a dramatic improvement in mass productivity.

What is claimed is:

1. A deposited-film formation apparatus for forming a deposited film on a substrate by;
generating plasma in a discharge space defined between a power-applying electrode and the substrate in a vacuum chamber, the substrate being servable as an electrode disposed opposingly to the power-applying electrode; and
decomposing a material gas fed into the vacuum chamber, wherein;
the substrate has a flexibility, and the power-applying electrode is provided with an undulation on its surface on the side of discharge space in such a way that the distance between the substrate and the power-applying electrode comes to be a desired value in agreement with the curving of the substrate.

2. The deposited-film formation apparatus according to claim 1, wherein the undulation is formed in agreement with the curving of the substrate in the course of its transportation.

3. A deposited-film formation apparatus for forming a deposited film on a substrate by;
generating plasma in a discharge space defined between a power-applying electrode and the substrate in a vacuum chamber, the substrate being servable as an electrode disposed opposingly to the power-applying electrode; and
decomposing a material gas fed into the vacuum chamber, wherein;
the power-applying electrode has a structure comprising a plurality of sheets or a plurality of columnar members which are bundled upright with respect to the substrate.

4. The deposited-film formation apparatus according to claim 3, wherein the substrate has a flexibility, and the power-applying electrode is an electrode which is pressed against the surface of the substrate in such a way that individual sheets or individual columnar members constituting the power-applying electrode come into contact with that surface at their upper ends so that a curved shape of the substrate is transferred to the surface of the power-applying electrode.

5. The deposited-film formation apparatus according to claim 3, wherein a means for pressing the power-applying electrode against the surface of the substrate in such a way that individual sheets or individual columnar members constituting the power-applying electrode come into contact with that surface is further provided at the power-applying electrode on its side opposite to the substrate side.

6. The deposited-film formation apparatus according to claim 3, which has a mechanism for transporting the substrate and wherein the surface that connects substrate-side ends of the plurality of sheets or plurality of columnar members is so formed as to be in agreement with the curving of the substrate in the course of its transportation.

7. A deposited-film formation process comprising the step of:
generating plasma in a discharge space defined between a power-applying electrode and the substrate in a vacuum chamber, the substrate being servable as an electrode disposed opposingly to the power-applying electrode; and
decomposing a material gas fed into the vacuum chamber, to form a deposited film on the substrate while the substrate is transported,
wherein;
the process further comprises the steps of:
providing the power-applying electrode with an undulation on its surface in agreement with the curving of the substrate in the course of its transportation; and
disposing the power-applying electrode in the vacuum chamber.

8. A deposited-film formation process comprising the steps of:
generating plasma in a discharge space defined between a power-applying electrode and the substrate in a vacuum chamber, the substrate being servable as an electrode disposed opposingly to the power-applying electrode; and
decomposing a material gas fed into the vacuum chamber, to form a deposited film on the substrate,
wherein;
the inside of the vacuum chamber is brought into conditions for forming the deposited film, and the deposited film is formed by generating the plasma after the power-applying electrode, constituted of a plurality of sheets or a plurality of columnar members which are bundled upright with respect to the substrate, is so pressed against the substrate as to come into contact with its surface to transfer a curved shape of the substrate to the surface of the power-applying electrode and then the power-applying electrode is separated from the surface of the substrate.
